(19) United States
(12) Patent Application Publication
(10) Pub. No.: US 2015/0171833 A1
(43) Pub. Date: Jun. 18, 2015

(54) GATE DRIVER CIRCUIT OUTPUTTING SUPERIMPOSED PULSES

(71) Applicants: Konkuk University Industrial Cooperation Corp, Seoul (KR); Electronics and Telecommunications Research Institute, Daejeon (KR)

(72) Inventors: Jae-Eun PI, Seongnam-si (KR); Sang-Hee PARK, Daejeon (KR); Min Ki RYU, Daejeon (KR); Chi-Sun HWANG, Daejeon (KR); OhSang KWON, Daejeon (KR); Eunsuk PARK, Daejeon (KR); Kee-Chan PARK, Seongnam-si (KR); YeonKyung KIM, Daejeon (KR)

(73) Assignees: Electronics and Telecommunications Research Institute, Seoul (KR); Konkuk University Industrial Cooperation Corp, Seoul (KR)

(21) Appl. No.: 14/335,242

(22) Filed: Jul. 18, 2014

(30) Foreign Application Priority Data
Dec. 13, 2013 (KR) 10-2013-0155593

(51) Int. Cl. H03K 3/012; H03K 5/01

(52) U.S. Cl. CPC H03K 3/012; H03K 5/01

(57) ABSTRACT

Provided is a gate driver circuit. The gate driver circuit includes a plurality of sequentially connected stages, and each of stages includes an input unit including two input transistors forming diode connection, a pull-up unit including a pull-up transistor and a bootstrap capacitor, and first and second pull-down units each including two transistors. According to embodiments, an input capacitor is further included which is connected to a node between the input unit and the pull-up unit. In addition, a carry unit is further included which is connected to an output terminal and formed to transmit an output signal in a high state or a low state to a next stage.

### CROSS-REFERENCE TO RELATED APPLICATIONS

This U.S. non-provisional patent application claims priority under 35 U.S.C. §119 of Korean Patent Application No. 10-2013-0155593, filed on Dec. 13, 2013, the entire contents of which are hereby incorporated by reference.

### BACKGROUND OF THE INVENTION

The present invention disclosed herein relates to a gate driver circuit driving a display apparatus.

As a display apparatus displaying an image, there are a liquid crystal display (LCD), a field emission display (FED), a plasma display panel (PDP), and an organic light emitting diode (OLED), etc.

These display apparatuses embed various circuits configured with thin film transistors (TFTs) for cost reduction and simplification of a module structure. For example, there is a gate driver circuit driving gate lines of a display apparatus.

An oxide TFT embedded in a gate driver circuit is more excellent in current driving capability than the existing amorphous silicon TFT and has a lower manufacturing cost. However, the oxide TFT is easily subject to stress due to a voltage and a light and, in many cases, has a negative threshold voltage due to a miniaturization process. Accordingly, when the existing silicon TFT based technology is used without any change, the transistor is not completely turned off and then the circuit would not normally operate. Furthermore, when the transistor has a negative threshold value, power consumption is rapidly increased.

In addition, as resolution increases to 4k level ultra high definition (UHD) (3840×2160 pixels) or 8k level UHD (7680×4320 pixels) which has recently got spotlight, all pixels in the current frame are required to be driven in a given time (for example, when a scanning rate is 60 Hz, all pixels in one frame are required to be driven for 1/60 second). As the resolution increases, a time for driving a gate line becomes shortened, thereby increasing charging failure. Accordingly, in order to secure sufficient charging time, it becomes important to control a signal output from a gate driver circuit.

### SUMMARY OF THE INVENTION

The present invention provides a gate driver circuit stably operating an oxide thin film transistor having depletion mode characteristics and reducing power consumption by applying a negative voltage to gates of main transistors of the gate driver circuit.

The present invention also provides a gate driver circuit elongating a charging time of a pixel by allowing an output waveform of each stage of the gate driver circuit to be superimposed in half with an output waveform of a previous stage.

Embodiments of the present invention provide gate driver circuits including a plurality of sequentially connected stages, wherein an Nth (where N is a natural number) stage includes: an input unit configured to deliver a first carry signal to a first node in response to the first carry signal delivered from an (N−1)th stage and a first clock signal; and a pull-up unit configured to pull-up an input signal according to a signal level at the first node and to deliver the pulled-up input signal to an output terminal, wherein the pull-up unit comprises a bootstrap capacitor provided between the first node and the output terminal to bootstrap a signal level at the first node to a high level.

In some embodiments, the input unit may include a first input transistor configured to deliver the first carry signal in response to the first clock signal; and a second input transistor configured to deliver the first carry signal to the first node in response to the first carry signal, wherein the first input transistor is connected between a gate electrode and a drain electrode of the second transistor.

In other embodiments, the input signal input to the Nth stage may be delayed than the signal input to the (N−1)th stage, and the input signal input to the Nth stage may be partially superimposed in a high level period with the input signal input to the (N−1)th stage.

In still other embodiments, a signal level at the first node may be bootstrapped at a point where the first carry signal is transitioned from a high level to a low level and the input signal is transitioned from a low level to a high level.

In even other embodiments, the pull-up unit may include a pull-up transistor configured to deliver the input signal to an output terminal in response to the signal level at the first node.

In yet other embodiments, the gate driver circuit may further include an input capacitor connected between a gate electrode of the first input transistor and the first node to lower a voltage of the first node by capacitive coupling.

In further embodiments, the gate driver circuit may further include: a first pull-down unit configured to ground the first node; and a second pull-down unit configured to ground the output terminal.

In still further embodiments, the first pull-down unit may include: a first pull-down transistor configured to deliver a signal at the first node in response to the first clock signal; and a second pull-down transistor configured to ground a signal delivered from the first pull-down transistor in response to a second carry signal delivered from an (N+2)th stage.

In even further embodiments, the second pull-down unit may include: a third pull-down transistor configured to ground the output terminal in response to the first clock signal; and a fourth pull-down transistor configured to ground the output terminal in response to a second carry signal delivered to a second node through a coupling capacitor or the input signal delivered to the second node through the pull-down capacitor.

In yet further embodiments, the gate driver circuit may further include a transistor configured to deliver the second node in response to the first clock signal.

In much further embodiments, capacitive coupling of the coupling capacitor and capacitive coupling of the pull-down capacitor may be cancelled.

In still much further embodiments, the gate driver circuit may further include a carry unit connected to the output terminal to deliver a signal from the output terminal to (N−2)th and (N+1)th stages or to a power supply voltage.

In even much further embodiments, the carry unit may include: a first carry transistor configured to deliver a signal from the output terminal to a third node in response to the second clock signal; and a second carry transistor configured to deliver a signal from the third node as the power supply voltage in response to a third clock signal, wherein the signal of the third node is a third carry signal delivered to input units of the (N−2)th stage and (N+1)th stage.

In yet much further embodiments, the first to third carry signals may have an identical amplitude and period, the third carry signal may be delayed by ⅙ period than the first carry signal, and the second carry signal may be delayed by ⅓ period than the third carry signal.

In still yet much further embodiments, the power supply voltage may be lower than a ground voltage.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 illustrates a gate driver circuit including a plurality of stages according to an embodiment of the present invention;

FIG. 2 is a circuit diagram illustrating each stage of FIG. 1;

FIG. 3 is a graph showing depletion type characteristics in an N-type oxide thin film transistor (TFT);

FIG. 4 shows waveforms of signals input to and output from a stage;

FIG. 5 illustrates an operation of the gate driver circuit in T1 period shown in FIG. 4;

FIG. 6 illustrates an operation of the gate driver circuit in T2 period shown in FIG. 4;

FIG. 7 illustrates an operation of the gate driver circuit in T3 period shown in FIG. 4;

FIG. 8 illustrates an operation of the gate driver circuit in T4 period shown in FIG. 4;

FIG. 9 illustrates an operation of the gate driver circuit in T5 period shown in FIG. 4;

FIG. 10 shows a simulation result of a gate driver circuit according to an embodiment of the present invention;

FIG. 11 is a graph showing power consumptions in a gate driver circuit according to an embodiment of the present invention and in a general gate driver circuit;

FIG. 12 shows output signals output from an output terminal of each state of a gate driver circuit according to an embodiment of the present invention; and

FIG. 13 shows a display apparatus to which a gate driver circuit according to an embodiment of the present invention is mounted.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

Below, a gate driver circuit outputting superimposed pulses and a display apparatus including the same is used for illustrating characteristics and functions of example embodiments. However, those skilled in the art can easily understand other advantages and performances of example embodiments according to the descriptions. Moreover, example embodiments may be implemented or applied through other embodiments. Besides, the detailed description may be amended or modified according to viewpoints and applications, not being out of the scope, technical idea and other objects of example embodiments.

It will also be understood that when a layer is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. It will be understood that when an element or layer is referred to as being “connected”, “coupled”, or “adjacent” to another element or layer, it may be directly connected, coupled, or adjacent to the other element or layer or intervening elements may be present.

Hereinafter, it will be described about an exemplary embodiment of the present invention in conjunction with the accompanying drawings.

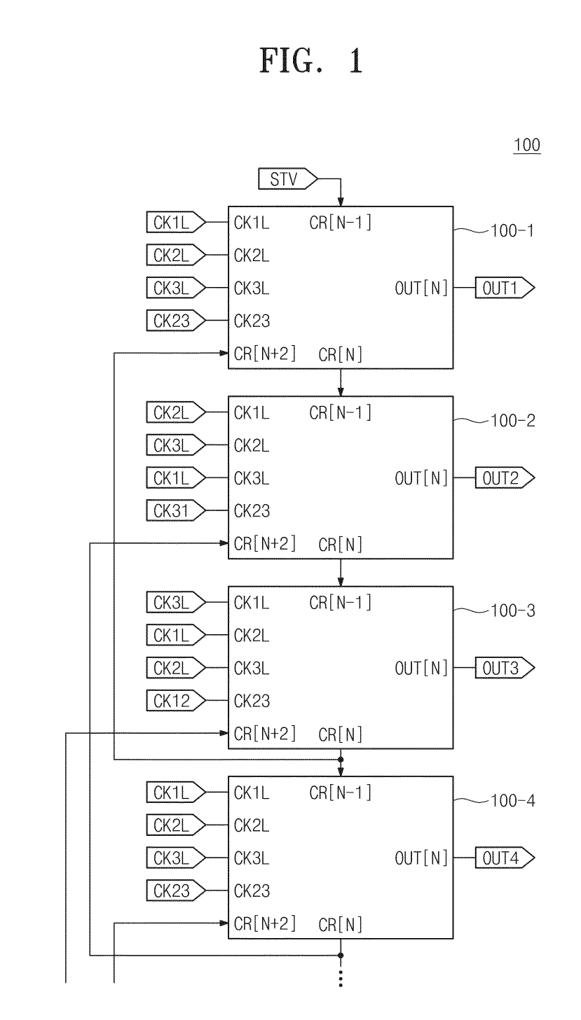

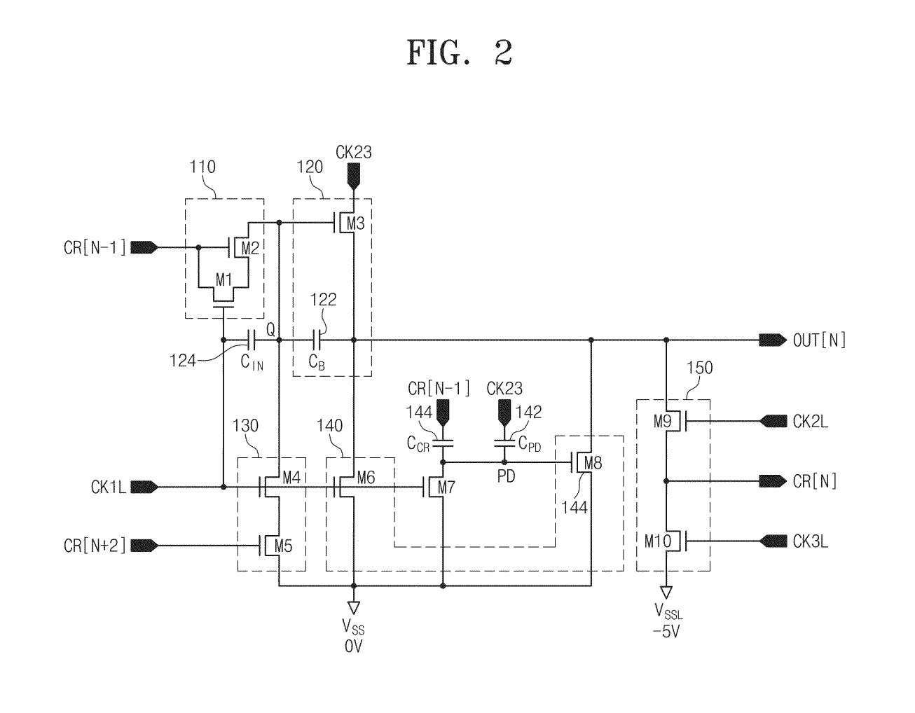

FIG. 1 illustrates a gate driver including a plurality of stages according to an embodiment of the present invention. Referring to FIG. 1, the gate driver may include the plurality of stages, and each of the plurality of stages may be configured with shift registers as shown in FIG. 2.

Signal input and output relationship between the plurality of stages is described based on a fourth stage 100-4. The fourth stage 100-4 may receive a carry signal from a carry terminal of a third stage 100-3 and output a carry signal to a carry terminal CR[N−1] of a fifth stage (not shown) and a carry terminal CR[N+2] of a second stage 100-2. Here, each of signals output to output terminals OUT 1 to OUT N may be used to drive a single gate line. For example, when a panel of a display apparatus driven by a gate driver has 4k level UHD (3840×2160 pixels) resolution, the numbers of stages and output terminals are respectively 2160.

However, for a first stage 100-1, since there is no carry signal to be received from a previous stage, a start signal STV may be input to a first carry terminal CR[N−1]. In addition, since the last two stages 100-(N−1) and 100-N cannot receive carry signals from other stages, each of them may receive the start signal STV through a second carry terminal CR[N+1].

Furthermore, clock signals CK1L, CK2L, and CK3L among six clock signals input to the fourth stage 100-4 are input to terminals CK1L, CK2L, and CK3L and one cyclically selected from among clock signals CK12, CK23, and CK31 may be input to each stage. For better understanding, as an example, in the third stage 100-3, a clock signal CK3L is input to a terminal CK1L, a clock signal CK1L is input to a CK2L terminal, a clock signal CK2L is input to a terminal CK3L terminal, and a clock signal CK12 is input to a terminal CK23.

Each stage pulls-up a signal (for example, the clock signal CK12, CK23, or CK31) input through the terminal CK23 and delivers the pulled-up signal to an output terminal OUT[N] or a third carry terminal CR[N]. At this time, a plurality of transistors in the stage switch clock signals and carry signals input into the stage and deliver to the output terminal. According to an embodiment of the present invention, due to the switching operation, a signal output from an output terminal OUT[N] of a current stage (for example, 100-4) may be superimposed in half in a high state (i.e. logic high) with a signal output from an output terminal OUT[N] of a previous stage (for example, 100-3) and output. Accordingly, a charging time for pixels can be elongated and then charging failure can be reduced. In the same manner, signals output from output terminals of two adjacent stages may be superimposed in half in a high state (i.e. logic high) with each other. Accordingly, a charging time for pixels can be elongated and then charging failure can be reduced.

FIG. 2 is a circuit diagram of each state of FIG. 1. Referring to FIG. 2, each stage may include an input unit 110, a pull-up unit 120, an input capacitor (C_{IN}) 126, a first pull-down unit 130, a second pull-down unit 140, and a carry unit 150.

The input unit 110 may include first and second input transistors M1 and M2, and receive a carry signal CR[N−1] input to a first carry terminal from a previous stage.

The pull-up unit 120 may include a pull-up transistor M3 and bootstrap capacitor C_{B}, and is driven by a carry signal switched by the second input transistor M2. The pull-up unit 120 may deliver a signal input to a clock terminal CK23 to an output terminal OUT[N]. In addition, signals (CK12, CK23, and CK31) having an identical amplitude and period are cyclically and alternately input to the pull-up unit 120. At this time, CK23 is delayed than CK12, and CK13 is delayed than CK23, and a high level period of each signal may be partially superimposed with each other. According to an embodiment of the present invention, a signal delivered to the output terminal OUT[N] may be delayed than a signal delivered to the output terminal OUT[N] of the previous stage.

When a signal input to an input terminal of the pull-up unit 120 or a signal delivered to an output terminal OUT[N] is required to maintain a low state (i.e. logic low), the first and second pull-down units 130 and 140 allow a signal at a node between the input unit 110 and the pull-up unit 120 or a signal output to the output terminal OUT[N] to be maintained in a low state. The first pull-down unit 130 may include first and second pull-down transistors M4 and M5, and the second pull-down unit 140 may include third and fourth pull-down transistors M6 and M8. The first pull-down unit 130 may receive the second carry signal CR[N+2] from the next stage but one, and the second pull-down unit 140 may receive the first carry signal CR[N−1] from the previous stage.

The carry unit 150 receives a signal delivered from the pull-up unit 120, generates a third carry signal CR[N], which is delivered to a next stage and the one before previous stage and delivers the third carry signal CR[N] to a third carry terminal. The carry unit 150 may include first and second carry transistors M9 and M10 respectively switched by the clock signals CK2L and CK3L. At this time, the first and second carry transistors M9 and M10 may perform switching operations to allow the third carry signal CR[N] to have a delayed waveform than the first carry signal CR[N−1].

According to an embodiment of the present invention, the first carry signal CR[N−1], which is input to the first carry terminal, becomes a high state (i.e. logic high), and then a signal input to the clock terminal CK23 becomes a high state. In addition, a signal output from an output terminal OUT[N] of a current stage is output to be superimposed in half in a time when the signal is output in a high state with a signal output from an output terminal OUT [N−1] of the previous stage. The signal output to the output terminal OUT [N] drives pixels included in a signal gate line. If timings of stages are controlled such that times when outputs from the two adjacent stages are in a high state are superimposed with each other, a charging time for pixels can be elongated and then charging failure can be reduced.

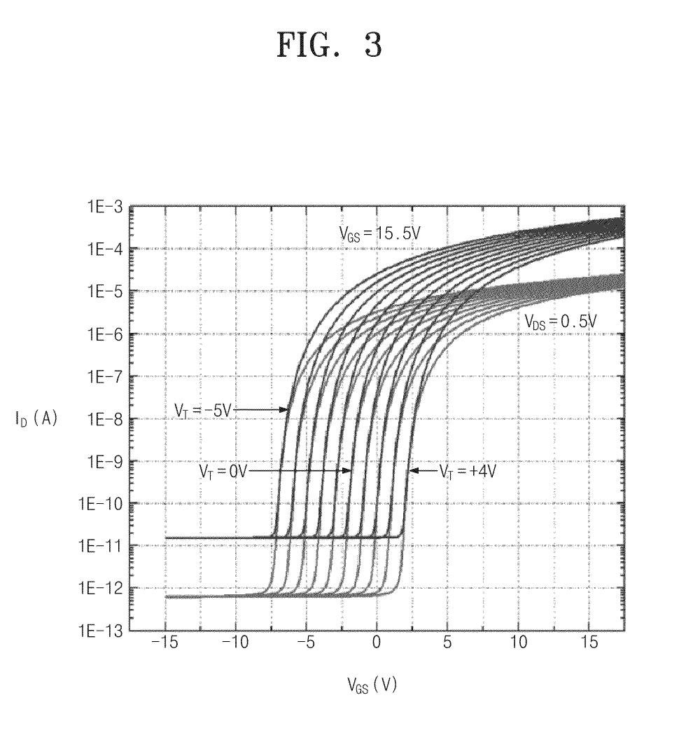

FIG. 3 is a graph showing depletion mode characteristics in an N-type oxide TFT. The horizontal and vertical axes respectively denote voltage V_{GS} between a gate and a source and a drain current I_{D}.

Referring to FIG. 3, despite of an enhancement mode transistor, a TFT may have depletion mode characteristics having a negative threshold voltage. The depletion mode characteristics refer to characteristics that the transistor is turned on in 0V state and, when a negative voltage is input to a gate, the transistor is turned off, although it is an enhancement mode transistor. Accordingly, in the present invention, by applying negative voltages to gates of the transistors forming the first pull-down unit 130 (in FIG. 2) and the second pull-down unit 140 (in FIG. 2), the transistors are explicitly turned off. Accordingly, leakage currents flowing through the transistors included in each gate driver can be reduced and then power consumption can be reduced.

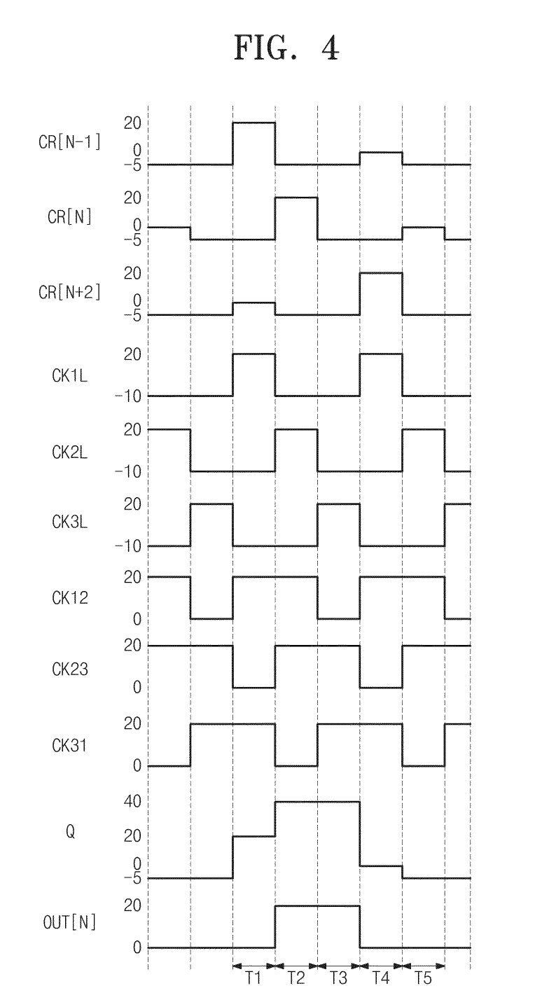

FIG. 4 shows waveforms of signals input to and output from the stages. Referring to FIG. 4, the clock signals CK1L, CK2L, CK3L, CK12, CK23, and CK31 are clock signals input to terminals of each stage. CR[N−1] and CR[N+2] respectively represent carry signals input to a previous stage and from one after next stage, and CR[N] represents a carry signal output to the next stage. OUT 1 to OUT N represent signals output through the output terminal OUT[N]. In addition, Q represents a voltage level at node Q shown in FIG. 1. For a gate driver circuit to be described below, a fourth stage 200-4 is exemplarily described. That is, a case where the clock signals CK1L, CK2L, CK3L, and CK23 respectively input to terminals CK1L, CK2L, CK3L, and CK23 is exemplarily described.

Referring FIGS. 1 and 4, the input unit 110 includes first and second input transistors M1 and M2. Drain electrodes of the first and second input transistors M1 and M2 may be connected to the first carry terminal and receive the first carry signal CR[N−1]. In such a way, connecting a drain electrode and a gate electrode of a transistor and using like a current source is referred to as diode connection. Furthermore, a source electrode of the first input transistor M1 may be connected to the drain electrode of the second input transistor M2. The first input transistor M1 may be turned on by a signal input through the first clock terminal CK1L and a signal delivered through a source electrode of the second input transistor M2 may drive the pull-up unit 120.

Here, the first and second input transistors M1 and M2 play a role of determining a voltage at node Q, which drives the pull-up transistor M3. If the first and second input transistors M1 and M2 are not completely turned off, a normal signal may not be delivered. That is, when node Q is a floating state, a carry signal of the previous stage, which is input to the first carry terminal, is weakly delivered to node Q, and then bootstrapping may not properly occur. As the result, a normal signal is not delivered through the output terminal OUT[N].

The pull-up unit 120 includes a pull-up transistor M3 and a pull-up capacitor 122. The pull-up unit 120 pulls-up a signal CK23 input to an input terminal thereof and delivers the pulled-up signal to the output terminal OUT[N]. In addition, signals CK12, CK23, and CK31 having an identical amplitude and period may be cyclically and alternately input to an input terminal of the pull-up unit 120. At this time, CK23 is delayed than CK12, CK31 is delayed than CK23, and high level (i.e. logic high) periods of the signals may be partially superimposed with each other. For example, high level periods of the signals may be superimposed with each other by ½. When a signal (for example, 20V) delivered from the second input transistor M2 is stored in node Q, the pull-up unit 120 pulls-up a voltage of node Q close to 40V by using a signal (for example, 20V) delivered from the pull-up transistor M3. Accordingly, the pull-up transistor M3 becomes able to deliver a signal input to the clock terminal CK23 to the output terminal OUT[N] without a threshold voltage drop. For example, the signal delivered to the output terminal OUT[N] may be delayed and output by ⅙ period than a signal delivered to the output terminal OUT[N] of the previous stage.

The first pull-down unit 130 includes first and second pull-down transistors M4 and M5. When a signal input to the clock terminal CK23 and a signal delivered to the output terminal OUT[N] are required to be in low state, a voltage at node Q may not be lowered to Vss (for example, 0V). At this time, the first pull-down unit 130 may lower the voltage at node Q.

The second pull-down unit 140 includes third and fourth pull-down transistors M6 and M8. This is for lowering a voltage of the output terminal OUT[N] to Vss (for example, 0V), when it is required that a signal input to the clock terminal CK23 is in a high state and a signal output to the output terminal OUT[N] is in a low state.

The carry unit 150 includes first and second carry transistors M9 and M10. In addition, the first and second carry transistors M9 and M10 are respectively switched by clock signals CK2L and CK3L. A signal delivered through the pull-up transistor M3 may be delivered to an output terminal OUT[N] and the carry unit 150. At this time, the clock signals CK2L and CK3L control timings when the first and second carry transistors M9 and M10 are switched, and a third carry signal CR[N] may be generated, which has an identical waveform to that of the first carry signal CR[N−1] but is delayed. For example, the third carry signal CR[N] may be delayed by ⅙ period than the first carry signal CR[N−1]. Furthermore, a second carry signal CR[N+2] may be delayed by ⅓ period than the third carry signal CR[N].

According to a gate driver of an embodiment of the present invention, a high state of a signal output to an output terminal OUT[N] of a current stage is superimposed with that of a signal output to an output terminal OUT[N−1] of a previous stage and output, thereby elongating charging time of pixels. In addition, transistors are completely turned off by applying negative voltages to main transistors in the gate driver circuit, and then a stable output waveform can be obtained.

Hereinafter, an operation of the gate driver circuit for each period is described in relation to a timing diagram of FIG. 4.

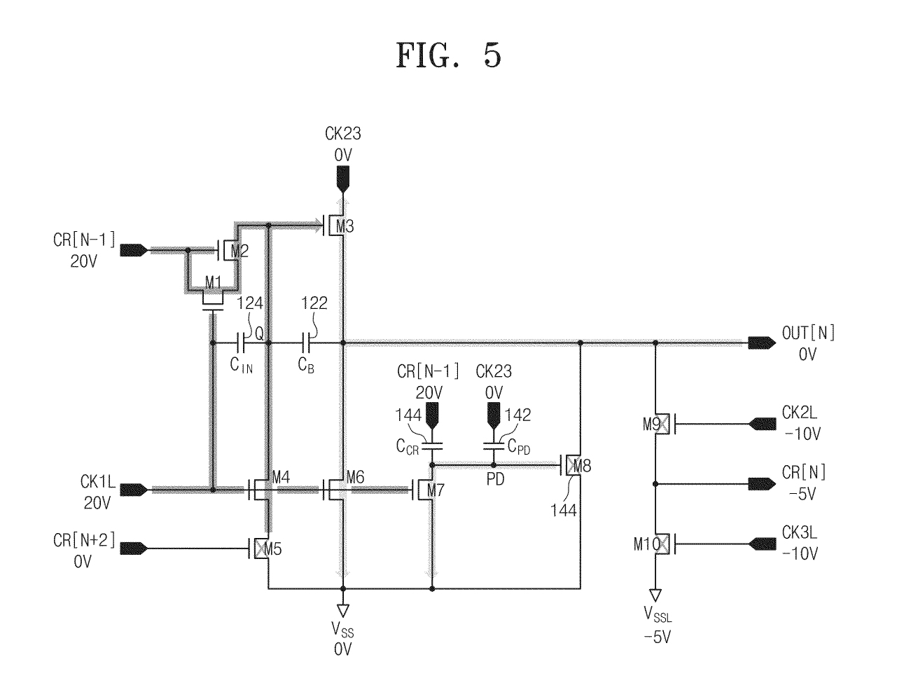

FIG. 5 illustrates an operation of the gate driver circuit in T1 period shown in FIG. 4. Referring to FIGS. 4 and 5, when 20V is input to a terminal CK1L and the first input transistor M1 is turned on, the first carry signal CR[N−1] of 20V input through the first carry terminal is delivered to a node Q through the second input transistor M2. In addition, since the pull-up transistor M3 is turned on and the first pull-down transistor M6 is turned on by 20V input to terminal CK1L, a voltage of the output terminal OUT[N] may be maintained as Vss (for example, 0V). In addition, since the transistor M7 is also turned on, a voltage of a node PD may be maintained as Vss (for example, 0V).

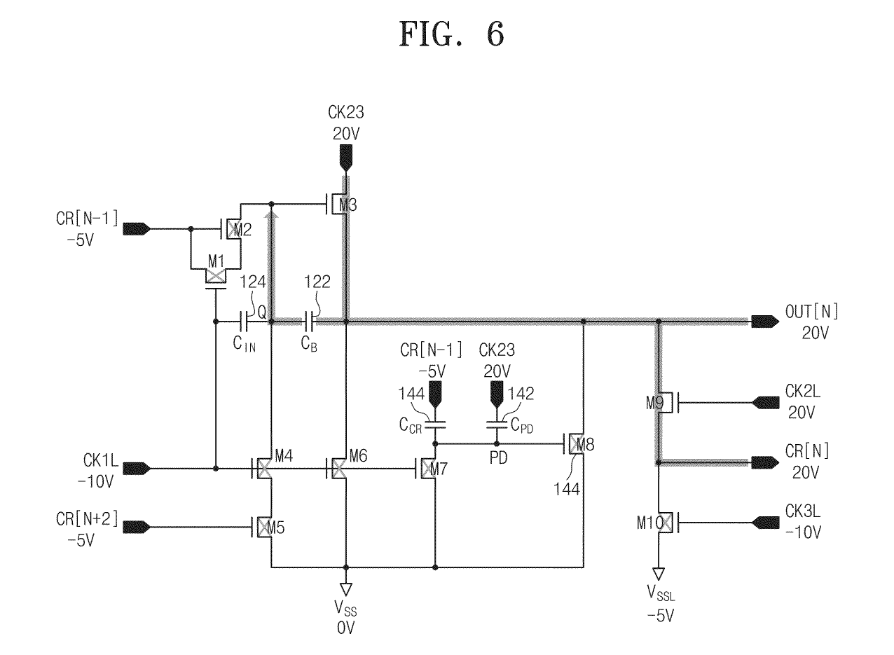

FIG. 6 illustrates an operation of the gate driver circuit in T2 period shown in FIG. 4. Referring to FIGS. 4 and 6, a signal input to the terminal CK1L becomes −10V, and the first input transistor M1, the third pull-down transistor M6, and the transistor M7 are turned off. Although the transistors have a negative threshold voltage due to the depletion mode characteristics of the oxide TFT, since negative voltages are applied to gates, the transistors M1, M6, and M7 are completely turned off. As the result, the node Q becomes a floating state due to the bootstrap capacitor C_{B}. In addition, a voltage at the node Q may be increased close to 40V due to a bootstrap effect by the pull-up transistor M3 and the bootstrap capacitor C_{B} according to a signal (20V) input to the terminal CK23. Briefly, since a voltage of 20V is provided to the output terminal OUT[N] in a state where a voltage at the node Q is 20V, the voltage at the node Q is charged to about 40V. Accordingly, the pull-up transistor M3 may deliver 20V input to terminal CK23 to the output terminal OUT[N] without a threshold voltage drop at the pull-up transistor M3. And, at the same time, the first carry transistor M9 may be turned on and deliver a third carry signal CR[N] of 20V to the next stage. At this time, capacitive coupling (namely, a voltage rise) by the pull-down capacitor C_{PD} between the node PD and the terminal CK23 may be cancelled by capacitive coupling (namely, a voltage drop) by the coupling capacitor C_{CR} between the node PD and the first carry terminal CR[N−1]. As a result, since the node PD may maintain a voltage of 0V or smaller, the pull-down transistor M8 may be completely turned off and a voltage of the output terminal OUT[N] may be maintained as 20V.

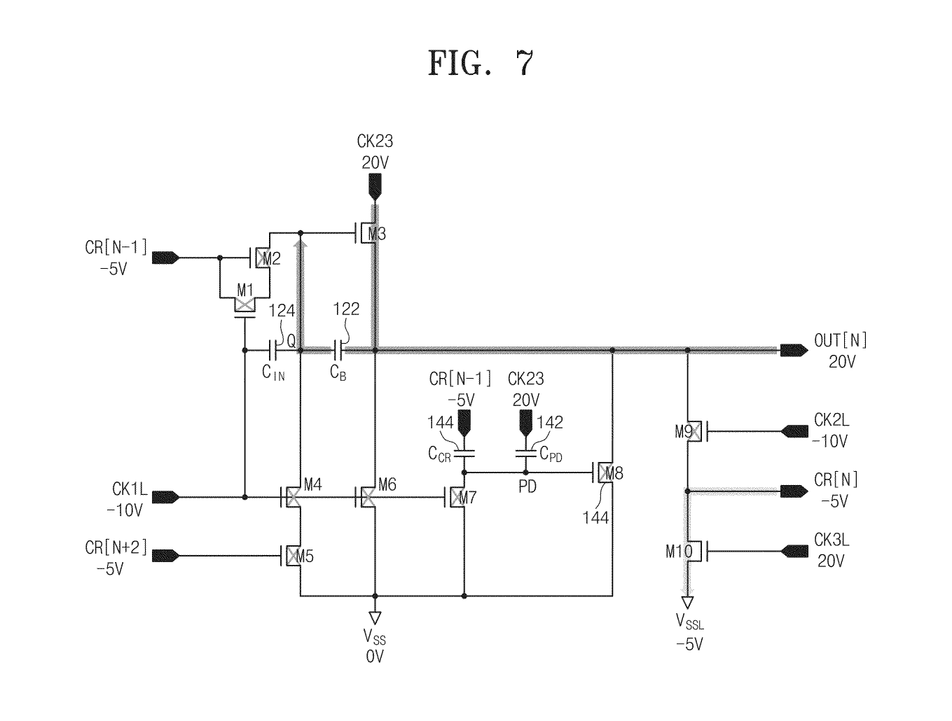

FIG. 7 illustrates an operation of a gate driver circuit in T3 period show in FIG. 4. Referring to FIGS. 4 and 7, the output terminal OUT[N] maintains 20V similar to the above-described T2 period. However, the first carry transistor M9 is completely turned off by a voltage of −10V input to the second clock terminal CK2L, and the second carry transistor M10 is turned on by a voltage of 20V input to the third clock terminal CK3L. Accordingly, the third carry terminal is connected to the second power supply voltage V_{SS} (for example, −5V) and the third carry signal CR[N] becomes −5V. Although described herein as −5V, it is obvious that the second power supply voltage V_{SSL} may be set within a lower range than the first power supply voltage VSS (for example, a ground voltage).

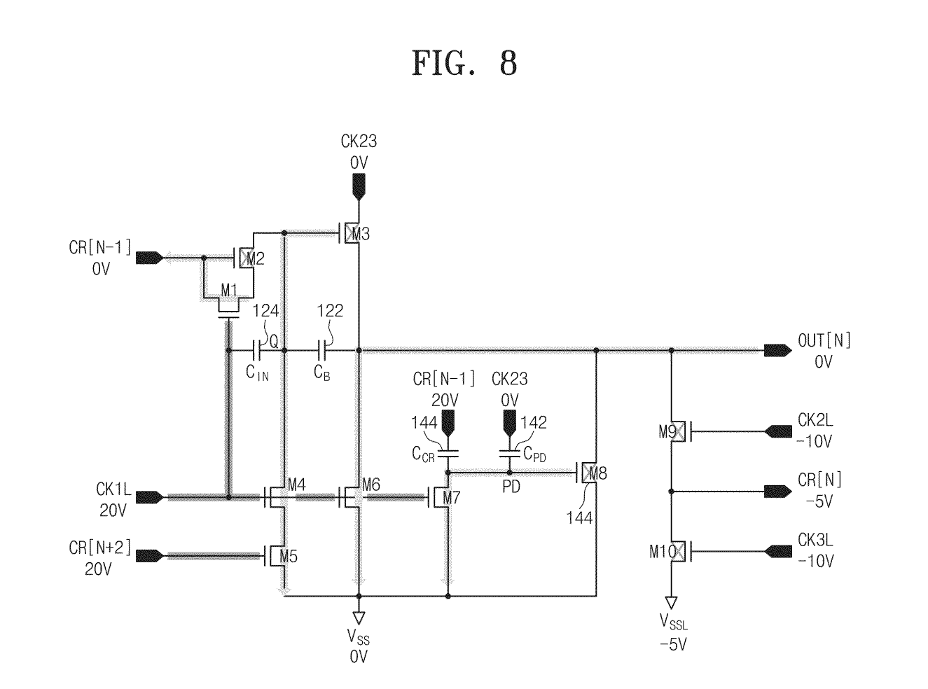

FIG. 8 illustrates an operation of the gate driver circuit in T4 period shown in FIG. 4. Referring to FIGS. 4 and 8, although a voltage of 20V is applied through the first clock terminal CK1L and the first input transistor M1 is turned on, since the first carry signal CR[N−1] of 0V is input through the first carry terminal, the second carry transistor M2 is turned off. That is, since the node Q and the first carry terminal are electrically separated, a high voltage at the node Q may prevent a voltage of the first carry terminal from being increased. In addition, since a voltage input to the clock terminal CK23 becomes lowered, a voltage at the node Q may be not lowered to V_{SS}. Accordingly, in order to pull down the voltage at the node Q, the second carry signal CR[N+1] of 20V is applied to the first clock terminal CK1L and the second carry terminal to turn on the first and second pull-down transistors M4 and M5. As a result, the node Q is connected to the first power supply voltage V_{SS} and pulled down to 0V. Furthermore, the transistor M7 is turned on by 20V input to the first clock terminal CK1L, and the node PD is pulled down to the first power supply voltage V_{SS} (for example, a ground voltage). As a result, the fourth pull-down transistor M8 may be turned off.

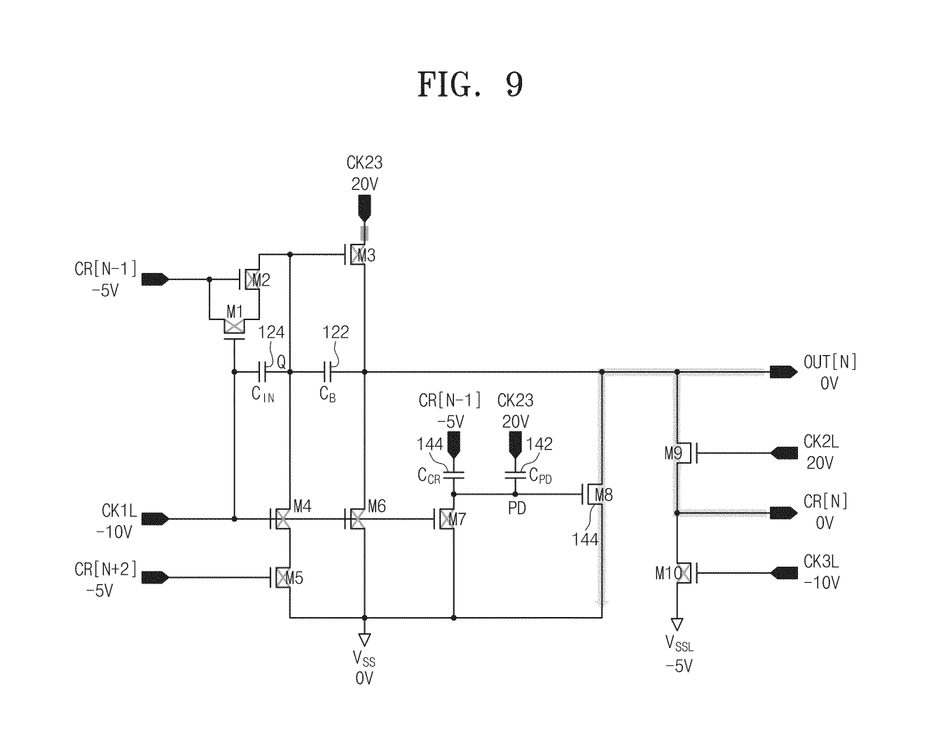

FIG. 9 illustrates an operation of the gate driver circuit in T5 period shown in FIG. 4. Referring to FIGS. 4 and 9, as −10V is input through the first clock terminal CK1L, a voltage at the node Q is lowered below 0V by capacitive coupling through C_{IN}. Accordingly, although the threshold voltage of the pull-up transistor M3 has a negative value, since the pull-up transistor M3 may be completely turned off, a leakage current may be reduced and power consumption may also be reduced. On the other hand, as 20V is input through the clock terminal CK23, a voltage at the node PD is increased through the pull-down capacitor C_{PD}. In addition, a voltage of the output terminal OUT[N] may be pulled down to V_{SS} (for example, 0V) while the fourth pull-down transistor M8 is turned on by the voltage at the node PD.

That is, when a voltage input through the first clock terminal CK1L is 20V, the output terminal OUT[N] may be pulled down through the third pull-down transistor M6. When a voltage input through the clock terminal CK23 is 20V, the output terminal OUT[N] may be pulled down through the fourth pull-down transistor M8.

Each stage of the gate driver maintains a voltage output through the output terminal OUT[N] as 20V when a voltage input through the clock terminal CK23 is 20V. In addition, a voltage output through the output terminal OUT[N] of the next stage is maintained as 20V, while the clock signal CK31 is 20V. That is, since times when voltages output through the output terminals OUT[N] of two adjacent stages are maintained as 20V are superimposed in half with each other, a pixel charging time may be elongated.

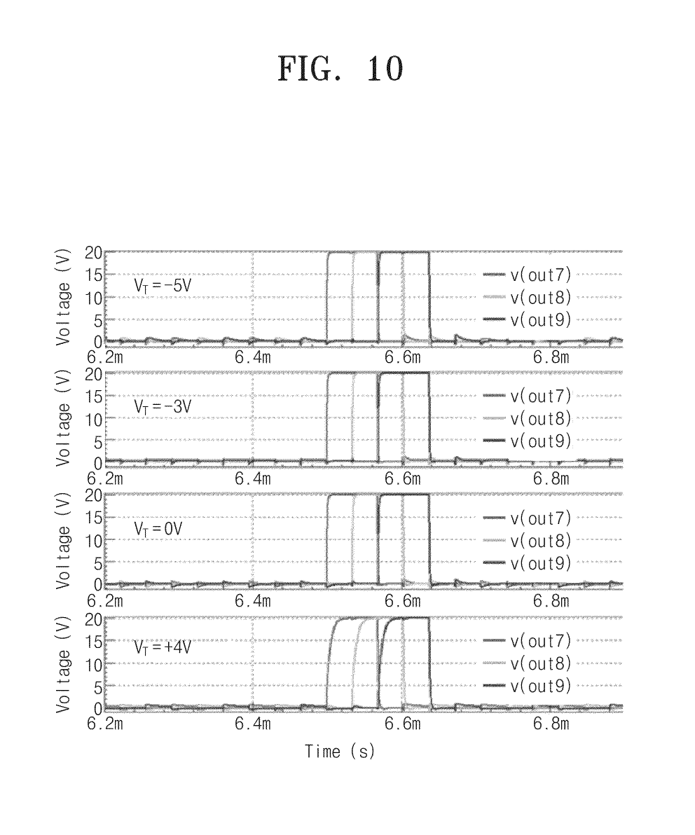

FIG. 10 illustrates a simulation result of a date driver circuit according to an embodiment of the present invention. Transistors respectively have threshold voltages V_{T}=−5, −3, 0, 4V, and output voltages of output terminals of seventh, eighth, and ninth stages are illustrated. Referring to FIG. 10, although a threshold voltage value of a transistor is changed, it can be noted that a voltage value and a waveform are maintained almost constantly and the gate driver circuit normally operates. In addition, although having a negative threshold voltage value, it can be noted that depletion mode characteristic limitation of an oxide TFT is solved.

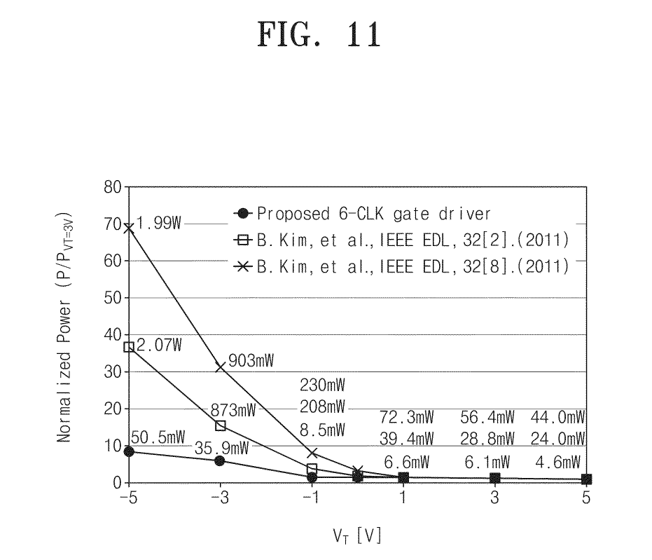

FIG. 11 is a graph showing consumption powers of a gate driver circuit according to an embodiment of the present invention and a general gate driver circuit. An experiment was performed on a case where a VGA level display was driven and power consumption was calculated for a gate driver circuit configured with 480 stages. In addition, in order to compare degrees that power consumption was increased when a threshold voltage of a transistor had a negative value, standardized values based on power consumption in case where a threshold voltage is 3V are shown as a graph. Referring to FIG. 11, although a threshold voltage of a transistor has a negative value, it can be seen that an increase amount in the power consumption of the gate driver according to an embodiment of the present invention may be significantly smaller than that of a general gate driver circuit.

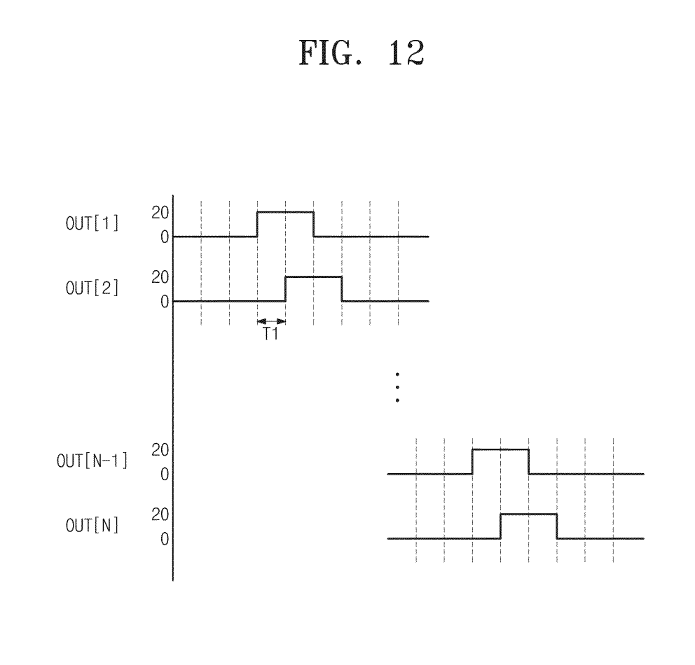

FIG. 12 illustrates an output signal output from an output terminal of each stage of a gate driver circuit according to an embodiment of the present invention. Referring to FIG. 12, high states of output signals (for example, OUT[1] and OUT[2] output from output terminals OUT[N] of two adjacent stages are superimposed with each other in half. Accordingly, pixel charging time can be elongated and power consumption can be significantly reduced by solving depletion mode characteristic limitation of an oxide TFT.

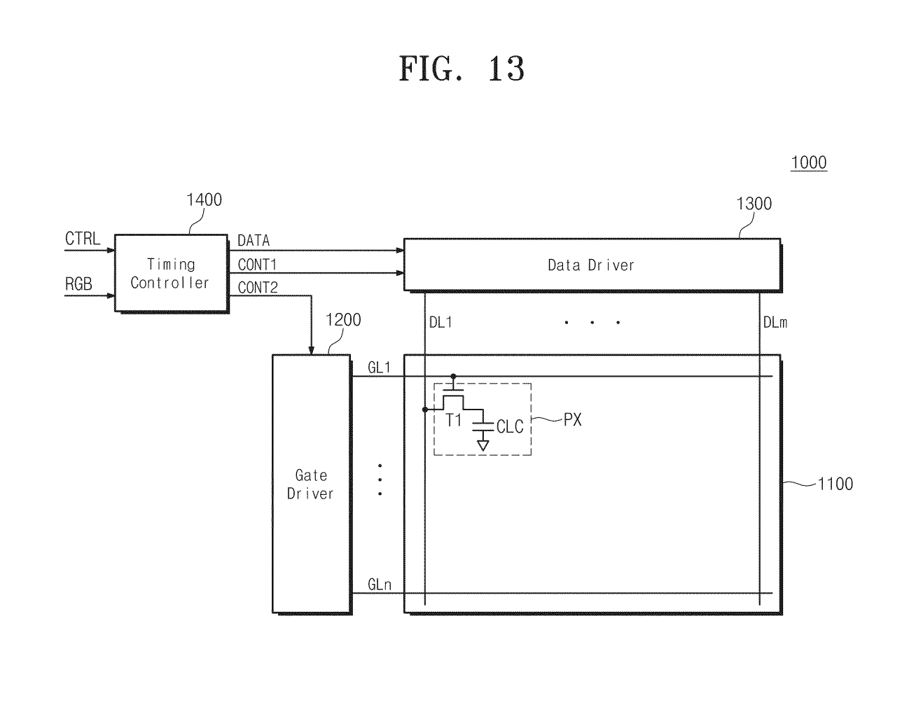

FIG. 13 illustrates a display apparatus to which a gate driver is mounted according to an embodiment of the present invention. Referring to FIG. 13, the display apparatus 1000 may include a display panel 1100, a gate driver 1200, a data driver 1300, and a timing controller 1400.

The display panel 1100 may include a plurality of data lines DL1 to DLm, a plurality of gate lines GL1 to GLn intersecting with the plurality of data lines DL1 to DLm, and a plurality of pixels PX disposed at points at which the plurality of data lines and the plurality of gate lines intersect with each other. The plurality of data lines DL1 to DLm and the plurality of gate lines GL1 to GLn are insulated from each other. Each pixel PX may include a switching transistor T1 connected to a corresponding data line and gate line and a liquid crystal capacitor (CLC) connected to the switching transistor T1.

The gate driver 1200 drives the plurality of gate lines GL1 to GLn in response to a second control signal CONT2 from the timing controller 1400. The data driver 1300 outputs grayscale voltages for driving the data lines DL1 to DLm according to a data signal DATA and a first control signal CONT1 from the timing controller 1400. The data driver 1300 includes data driving integrated circuits 141 to 144 shown in FIG. 1.

While a gate driving signal of a gate on voltage (VON) level is applied to any one gate line among the plurality of gate lines GL1 to GLn by the gate driver 1200, the switching transistor T1 connected to the gate driver 1200 is turned on and the grayscale voltages from the data driver 1300 may be provided to the data lines DL1 to DLm.

The timing controller 1400 may receive externally an image signal RGB and control signals (CTRL), for example, a vertical sync signal, a horizontal sync signal, a main clock signal, and a data enable signal, etc., for controlling display of the image signal. The timing controller 1400 may provide a data signal DATA and the first control signal CONT1 that an image signal RGB is processed properly to an operation condition of the display panel 1100 in response to the control signals CTRL, and provide a second control signal CONT2 to the gate driver 1200. The first control signal CONT1 may include a horizontal sync start signal, a clock signal, and a line latch signal, and the second control signal CONT2 may include a vertical sync start signal and an output enable signal.

According to embodiments of the present invention, an oxide thin film transistor having depletion mode characteristics can be stably operated and power consumption can also be reduced by supplying a negative voltage to gates of main transistors of a gate driver circuit.

In addition, a charging time of a pixel can be elongated by allowing an output waveform of each stage of a gate driver circuit to be superimposed in half with an output waveform of a previous stage.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A gate driver circuit comprising a plurality of sequentially connected stages, an Nth (where N is a natural number) stage comprising:
an input unit configured to deliver a first carry signal to a first node in response to the first carry signal delivered from an (N−1)th stage and a first clock signal; and
a pull-up unit configured to pull-up an input signal according to a signal level at the first node and to deliver the pulled-up input signal to an output terminal,
wherein the pull-up unit comprises a bootstrap capacitor provided between the first node and the output terminal to bootstrap a signal level at the first node to a high level.

2. The gate driver circuit of claim 1, wherein the input unit comprises a first input transistor configured to deliver the first carry signal in response to the first clock signal; and
a second input transistor configured to deliver the first carry signal to the first node in response to the first carry signal,
wherein the first input transistor is connected between a gate electrode and a drain electrode of the second transistor.

3. The gate driver circuit of claim 2, wherein the input signal input to the Nth stage is delayed than the signal input to the (N−1)th stage, and the input signal input to the Nth stage is partially superimposed in a high level period with the input signal input to the (N−1)th stage.

4. The gate driver circuit of claim 3, wherein a signal level at the first node is bootstrapped at a point where the first carry signal is transitioned from a high level to a low level and the input signal is transitioned from a low level to a high level.

5. The gate driver circuit of claim 4, wherein the pull-up unit comprises:
a pull-up transistor configured to deliver the input signal to an output terminal in response to the signal level at the first node.

6. The gate driver circuit of claim 5, further comprising an input capacitor connected between a gate electrode of the first input transistor and the first node to lower a voltage of the first node by capacitive coupling.

7. The gate driver circuit of claim 5, further comprising:
a first pull-down unit configured to ground the first node; and
a second pull-down unit configured to ground the output terminal.

8. The gate driver circuit of claim 7, wherein the first pull-down unit comprises:
a first pull-down transistor configured to deliver a signal at the first node in response to the first clock signal; and
a second pull-down transistor configured to ground a signal delivered from the first pull-down transistor in response to a second carry signal delivered from an (N+2)th stage.

9. The gate driver circuit of claim 8, wherein the second pull-down unit comprises:
a third pull-down transistor configured to ground the output terminal in response to the first clock signal; and
a fourth pull-down transistor configured to ground the output terminal in response to a second carry signal delivered to a second node through a coupling capacitor or the input signal delivered to the second node through the pull-down capacitor.

10. The gate driver circuit of claim 9, further comprising a transistor configured to ground the second node in response to the first clock signal.

11. The gate driver circuit of claim 9, wherein capacitive coupling of the coupling capacitor and capacitive coupling of the pull-down capacitor are cancelled.

12. The gate driver circuit of claim 10, further comprising a carry unit connected to the output terminal to deliver a signal from the output terminal to (N−2)th and (N+1)th stages or to a power supply voltage.

13. The gate driver circuit of claim 12, wherein the carry unit comprises:
a first carry transistor configured to deliver a signal from the output terminal to a third node in response to the second clock signal; and
a second carry transistor configured to deliver a signal from the third node as the power supply voltage in response to a third clock signal,
wherein the signal of the third node is a third carry signal delivered to input units of the (N−2)th stage and (N+1)th stage.

14. The gate driver circuit of claim 13, wherein the first to third carry signals have an identical amplitude and period, the third carry signal is delayed by ⅙ period than the first carry signal, and the second carry signal is delayed by ⅓ period than the third carry signal.

15. The gate driver circuit of claim 13, wherein the power supply voltage is lower than a ground voltage.
